(19) United States
(12) Patent Application Publication
(10) Pub. No.: US 2019/0276778 A1
(43) Pub. Date: Sep. 12, 2019

(54) COMPOSITION FOR SEMICONDUCTOR PROCESS AND SEMICONDUCTOR PROCESS

(71) Applicant: SKC CO., LTD., Gyeonggi-do (KR)

(72) Inventors: Byoungsoo KIM, Gyeonggi-do (KR); Gyu An JIN, Gyeonggi-do (KR); Jun Rok OH, Seoul (KR)

(21) Appl. No.: 16/293,453

(22) Filed: Mar. 5, 2019

(30) Foreign Application Priority Data
Mar. 6, 2018 (KR) 10-2018-0026265

(51) Int. Cl. C11D 11/00; C11D 7/08; C11D 7/26; C11D 7/04; C11D 7/20; C11D 7/10; C11D 7/50; C09K 13/06; H01L 21/311; H01L 21/02

(52) U.S. Cl. CPC C11D 11/0047; C11D 7/08; C11D 7/265; C11D 7/04; C11D 7/20; H01L 21/02068; C11D 7/10; C11D 7/5022; C09K 13/06; H01L 21/31111; C11D 7/26

(57) ABSTRACT

Provided are a composition for a semiconductor process, which comprises a first component comprising an inorganic acid or an organic acid; and a second component comprising a silicon compound represented by Formula 1 or 2, and a semiconductor process, which comprises selectively cleaning and/or removing an organic substance or an inorganic substance using the composition.

### TECHNICAL FIELD

Embodiments relate to a composition applied to a semiconductor process and a semiconductor process using the same.

### BACKGROUND ART

Semiconductors are fabricated by forming a pattern by various processes on a wafer made of silicon (Si), gallium arsenide (GaAs), or the like as a base material. Such a process for fabricating a semiconductor is comprised of multiple steps in which various organic or inorganic materials are used. Specifically, the semiconductor process comprises such steps as a wafer production process, an oxidation process, an exposure process, an etching process, an ion implantation process, a deposition process, a polishing process, and a cleaning process.

Specifically, in the wafer production process, silicon that exists in the form of silica or silicate is processed into polycrystalline silicon and then processed into monocrystalline silicon by a physical refining method. Such monocrystalline silicon is grown to produce a cylinder-shaped ingot, which is thinly cut and polished to produce a disk-shaped wafer.

In the oxidation process, the wafer is oxidized to form a silicon oxide film on the surface thereof. The oxide film formed on the surface of a wafer serves as a protective film in the diffusion process, protects and stabilizes the surface, and ensures the electrical insulation of the surface.

In the exposure process, a circuit pattern is formed on the surface of a wafer by using a mask having an image of a circuit. A photoresist is thinly coated on the surface of a wafer to form a photoresist film, and light is irradiated using an exposure apparatus to form a circuit on the wafer. The photoresist film may serve as a protective film in the etching process, the ion implantation process, and the like. The exposure process may be carried out using an electron beam or an X-ray other than light.

In the etching process, the surface of a wafer on which the photoresist film pattern has been formed is selectively removed. The etching process is divided into a wet process and a dry process. In the wet process, an etching solution is used for the etching. In the dry process, plasma, sputter, ion beam, or the like is used for the etching.

In the ion implantation process, dopant ions are implanted into a wafer to make it a semiconductor. A wafer does not conduct electricity in a pure state. When ions are implanted through the ion implantation process, then it allows electricity to flow.

In the deposition process, a material having electrical characteristics is deposited on a wafer. As the deposition method, such a method as chemical vapor deposition (CVD) or physical vapor deposition (PVD) may be used.

In the polishing process, a rough surface of a wafer is polished to form a mirror-surface planarized region. The polishing process is carried out using a chemical and/or mechanical method, which may be referred to as a CMP (chemical mechanical polishing) process. In the CMP process, both the chemical action and the physical action are simultaneously applied to polish the wafer surface.

The cleaning process refers to any process for removing impurities of a wafer. The cleaning process removes unnecessary organic or inorganic substances from the wafer surface, thereby facilitating the subsequent processes.

These various semiconductor processes can be designed in an appropriate order as needed to produce high-quality semiconductors with various functions. In addition, various compositions are used in such semiconductor processes. Since the process efficiency and final physical properties of a wafer vary depending on such a composition, it is one of the important tasks to design a composition suitable for each purpose.

### DISCLOSURE OF THE INVENTION

### Technical Problem

An embodiment of the present invention provides a composition for a semiconductor process, wherein the composition is applied to the semiconductor process to provide a wafer that has excellent surface properties.

Another embodiment of the present invention provides a semiconductor process, which is carried out using the composition for a semiconductor process.

### Solution to the Problem

In an embodiment of the present invention, there is provided a composition for a semiconductor process, which comprises a first component comprising an inorganic acid or an organic acid; and a second component comprising a compound represented by the following Formula 1 or a compound represented by the following Formula 2.

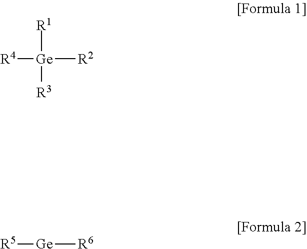

In the above Formulae 1 and 2, R¹ to R⁶ each independently may be selected from hydrogen, a substituted or unsubstituted C₁-C₃₀ alkyl group, a substituted or unsubstituted C₁-C₃₀ alkoxy group, a substituted or unsubstituted C₂-C₃₀ alkenyl group, a substituted or unsubstituted C₂-C₃₀ alkynyl group, a substituted or unsubstituted C₆-C₃₀ aliphatic ring group, a substituted or unsubstituted C₄-C₃₀ heteroaliphatic ring group, a substituted or unsubstituted C₆-C₃₀ aromatic ring group, a substituted or unsubstituted C₄-C₃₀ heteroaromatic ring group, a substituted or unsubstituted amine group, a hydroxyl group, a carbonyl group, a carboxyl group, a halogen group, an oxide (═O) group, and a group of the following Formula 3.

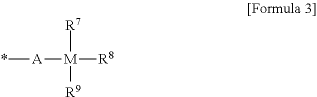

In the above Formula 3, M is silicon (Si) or germanium (Ge), A is selected from a single bond, a substituted or unsubstituted C₁-C₃₀ alkylene group, a substituted or unsubstituted C₂-C₃₀ alkenylene group, a substituted or unsubstituted C₂-C₃₀ alkynylene group, a substituted or unsubstituted divalent C₆-C₃₀ aliphatic ring group, a substituted or unsubstituted divalent C₄-C₃₀ heteroaliphatic ring group, a substituted or unsubstituted divalent C₆-C₃₀ aromatic ring group, a substituted or unsubstituted divalent C₄-C₃₀ heteroaromatic ring group, a substituted or unsubstituted divalent amine group, —O—, —S—, S(═O)₂— and —C(═O)—, and

R⁷ to R⁹ are each independently selected from hydrogen, a substituted or unsubstituted C₁-C₃₀ alkyl group, a substituted or unsubstituted C₁-C₃₀ alkoxy group, a substituted or unsubstituted C₂-C₃₀ alkenyl group, a substituted or unsubstituted C₂-C₃₀ alkynyl group, a substituted or unsubstituted C₆-C₃₀ aliphatic ring group, a substituted or unsubstituted C₄-C₃₀ heteroaliphatic ring group, a substituted or unsubstituted C₆-C₃₀ aromatic ring group, a substituted or unsubstituted C₄-C₃₀ heteroaromatic ring group, a substituted or unsubstituted amine group, a hydroxyl group, a carbonyl group, a carboxyl group, a halogen group, and an oxide (═O) group.

In another embodiment of the present invention, there is provided a semiconductor process, which comprises a cleaning process wherein an organic substance or an inorganic substance is selectively cleaned using the composition for a semiconductor process; a removal process wherein an organic substance or an inorganic substance is selectively removed using the composition for a semiconductor process; or both of them.

### Advantageous Effects of the Invention

The composition for a semiconductor process is a composition in which specific components are appropriately blended. It can be applied to a semiconductor process that meets the production purposes to perform an excellent function. A semiconductor fabricated through the process can have improved qualities.

### DETAILED DESCRIPTION FOR CARRYING OUT THE INVENTION

The advantages and features of the present invention and the methods of achieving them will become apparent with reference to the embodiments described hereinafter. However, the present invention is not limited to the embodiments described below, but may be embodied in various different forms. These embodiments are provided so that the disclosure of the present invention will be thorough and complete, and will fully convey the scope of the invention to those skilled in the art. The invention is defined by only the scope of the claims.

In addition, all numerical ranges and expressions related to the amount of a component, reaction conditions, and the like used herein are to be understood as being modified by the term “about,” unless otherwise indicated.

In addition, the term “substituted” as used herein means to be substituted with at least one selected from the group consisting of deuterium, a halogen group (—F, —Cl, —Br, —I), a hydroxyl group, a cyano group, a nitro group, an amino group, an amidino group, a hydrazine group, a hydrazone group, an ester group, a ketone group, a carboxyl group, a substituted or unsubstituted alkyl group, a substituted or unsubstituted alkenyl group, a substituted or unsubstituted alkynyl group, a substituted or unsubstituted alkoxy group, a substituted or unsubstituted alicyclic organic group, a substituted or unsubstituted hetero ring group, a substituted or unsubstituted aryl group, and a substituted or unsubstituted heteroaryl group. The substituents enumerated above may be connected to each other to form a ring.

The terms first, second, and the like are used herein to describe various components, and the components should not be limited by the terms. The terms are used only for the purpose of distinguishing one component from another.

In an embodiment of the present invention, there is provided a composition for a semiconductor process, which comprises a first component comprising an inorganic acid or an organic acid; and a second component comprising a compound represented by the following Formula 1 or a compound represented by the following Formula 2.

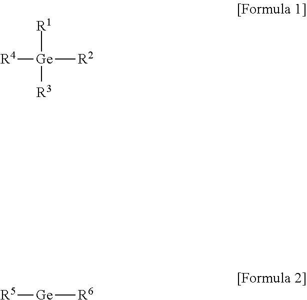

In the above Formulae 1 and 2, R¹ to R⁶ each independently may be selected from hydrogen, a substituted or unsubstituted C₁-C₃₀ alkyl group, a substituted or unsubstituted C₁-C₃₀ alkoxy group, a substituted or unsubstituted C₂-C₃₀ alkenyl group, a substituted or unsubstituted C₂-C₃₀ alkynyl group, a substituted or unsubstituted C₆-C₃₀ aliphatic ring group, a substituted or unsubstituted C₄-C₃₀ heteroaliphatic ring group, a substituted or unsubstituted C₆-C₃₀ aromatic ring group, a substituted or unsubstituted C₄-C₃₀ heteroaromatic ring group, a substituted or unsubstituted amine group, a hydroxyl group, a carbonyl group, a carboxyl group, a halogen group, an oxide (═O) group, and a group of the following Formula 3.

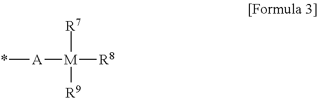

In the above Formula 3, M is silicon (Si) or germanium (Ge), A is selected from a single bond, a substituted or unsubstituted C₁-C₃₀ alkylene group, a substituted or unsubstituted C₂-C₃₀ alkenylene group, a substituted or unsubstituted C₂-C₃₀ alkynylene group, a substituted or unsubstituted divalent C₆-C₃₀ aliphatic ring group, a substituted or unsubstituted divalent C₄-C₃₀ heteroaliphatic ring group, a substituted or unsubstituted divalent C₆-C₃₀ aromatic ring group, a substituted or unsubstituted divalent C₄-C₃₀ heteroaromatic ring group, a substituted or unsubstituted divalent amine group, —O—, —S(═O)₂— and —C(═O)—, and

R⁷ to R⁹ are each independently selected from hydrogen, a substituted or unsubstituted C₁-C₃₀ alkyl group, a substituted or unsubstituted C₁-C₃₀ alkoxy group, a substituted or unsubstituted C₂-C₃₀ alkenyl group, a substituted or unsubstituted C₂-C₃₀ alkynyl group, a substituted or unsubstituted C₆-C₃₀ aliphatic ring group, a substituted or unsubstituted C₄-C₃₀ heteroaliphatic ring group, a substituted or unsubstituted C₆-C₃₀ aromatic ring group, a substituted or unsubstituted C₄-C₃₀ heteroaromatic ring group, a substituted or unsubstituted amine group, a hydroxyl group, a carbonyl group, a carboxyl group, a halogen group, and an oxide (═O) group.

In an embodiment, the second component may comprise the compound of the above Formula 1. in the above Formula 1, R¹ to R⁴ each independently may be selected from a substituted or unsubstituted C₁-C₃₀ alkyl group, a substituted or unsubstituted C₁-C₃₀ alkoxy group, a hydroxyl group, a carbonyl group, a carboxyl group, a halogen group, an oxide (═O), and the group of the above Formula 3.

In such event, in the case where M is silicon (Si) in the above Formula 3, A may be selected from a single bond and —O—, and R⁷ to R⁹ each independently may be selected from a substituted or unsubstituted C₁-C₃₀ alkyl group and a halogen group.

Meanwhile, in the case where M is germanium (Ge) in the above Formula 3, A may be selected from a single bond and —O—, and R⁷ to R⁹ each independently may be selected from a substituted or unsubstituted C₁-C₃₀ alkyl group, a carbonyl group, a carboxyl group, and an oxide (═O) group.

In another embodiment, the second component may comprise the compound of the above Formula 2. in the above Formula 2, R⁵ and R⁶ each independently may be selected from a halogen group and an oxide (═O) group.

Specifically, the second component may comprise at least one of the compounds represented by the following Formulae 1-1 to 1-10.

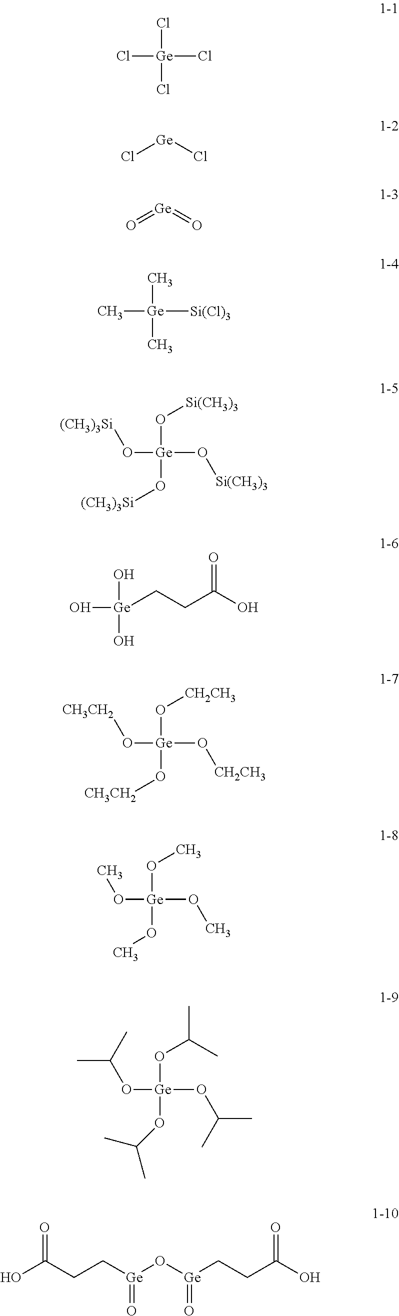

In the above Formulae 1 to 3, germanium (Ge) may be divalent or tetravalent. In addition, if an oxide (═O) group is comprised in R¹ to R⁴, two groups of R¹ to R⁴ may be combined to form one oxide (═O) group. Similarly, if an oxide (═O) group is comprised in R⁷ to R⁹, two groups of R⁷ to R⁹ may be combined to form one oxide (═O) group.

In the above Formula 3, * represents a bonding position.

As described above, the composition for a semiconductor process comprises, as the second component, a compound that contains divalent or tetravalent germanium (Ge) as a core metal. Thus, it can have excellent selectivity in cleaning or etching and removal processes.

The composition for a semiconductor process may further comprise a reaction product of the first component and the second component.

Specifically, when the composition for a semiconductor process is applied to a semiconductor process, the first component and the second component may be sequentially applied, or the first component and the second component may be mixed in advance and then applied.

In the case where the first component and the second component are sequentially applied to a semiconductor process, the reaction product of the two components is formed in the semiconductor process, which is contained in the composition for a semiconductor process. Meanwhile, in the case where the first component and the second component are mixed in advance and then applied to a semiconductor process, the reaction product of the two components may be already formed in the composition for a semiconductor process before the application thereof to the semiconductor process, or the reaction product may be formed at a specific temperature condition after the composition for a semiconductor process is applied to the semiconductor process.

Meanwhile, when the composition for a semiconductor process is applied to a semiconductor process, it may be possible that the first components react with each other or the second components react with each other under specific process conditions of the semiconductor process. In such event, the composition for a semiconductor process may further comprise a reaction product of the first components; or a reaction product of the second components.

The composition for a semiconductor process may further comprise a solvent depending on the application thereof. Specifically, the solvent may comprise water or a polar organic solvent. In such event, the composition for a semiconductor process has an advantage of a high cleaning or removing effect as compared with the case where a nonpolar organic solvent is used.

In an embodiment, the polar organic solvent may comprise at least one selected from the group consisting of alcohol, glycol, lactone, lactam, sulfoxide, sulfone, amide, urea, imidazolidinone, nitrile, and pyrrolidone.

The content of the solvent in the composition for a semiconductor process may be determined within a range in which the sum of the total content of the components excluding the solvent and the content of the solvent is 100% by weight in total.

The first component is an acid component that performs an oxidizing action in the composition for a semiconductor process. It may comprise an inorganic acid, an organic acid, or both.

In an embodiment, the content of the first component in the composition for a semiconductor process may be about 50% by weight to about 99% by weight, for example, about 50% by weight to about 90% by weight, for example, about 70% by weight to about 90% by weight, for example about 75% by weight to about 90% by weight, for example about 75% by weight to about 85% by weight. In such event, the composition for a semiconductor process may be suitable for use in an etching application.

In another embodiment, the content of the first component in the composition for a semiconductor process may be about 0.5% by weight to about 30% by weight, for example, about 0.5% by weight to about 10% by weight, for example, about 0.5% by weight to about 5% by weight. In such event, the composition for a semiconductor process may be suitable for use in a cleaning application.

Specifically the inorganic acid may comprise at least one selected from the group consisting of sulfuric acid, nitric acid, phosphoric acid, silicic acid, boric acid, hydrochloric acid, hydrofluoric acid, and perchloric acid. In addition, the organic acid may comprise at least one selected from the group consisting of acetic acid, formic acid, gluconic acid, lactic acid, oxalic acid, and hydrocarbonic acid.

In an embodiment, the first component may comprise at least one selected from the group consisting of sulfuric acid, phosphoric acid, and hydrofluoric acid. In the case where the first component comprises sulfuric acid, the function of removing organic substances may be enhanced. In the case where it comprises hydrofluoric acid, the cleaning function may be enhanced. In the case where it comprises phosphoric acid, the function of removing a metal nitride film may be enhanced.

The second component serves to form a protective film for a specific component in the semiconductor process or to assist in etching or removing a specific component. The content of the second component in the composition for a semiconductor process may be greater than about 0.001% by weight less than about 2% by weight, for example, about 0.01% by weight to about 1% by weight.

The composition for a semiconductor process may further comprise various additives depending on the applications and purposes thereof. Specifically, the additive may comprise at least one selected from the group consisting of a surfactant and a corrosion inhibitor, but it is not limited thereto.

More specifically, the composition for a semiconductor process may comprise, as an additive, hydrogen peroxide, a persulfate, a cyclic amine compound, an ammonium fluoride compound, a transition metal salt, a potassium compound, a urea fluoride, and the like.

The composition for a semiconductor process has properties suitable for application to a semiconductor process according to the composition as described above. Specifically, the composition for a semiconductor process may satisfy specific conditions for the activity thereof to a metal film or a metal oxide film.

More specifically, the composition for a semiconductor process may have an etching selectivity ratio for a metal nitride film to a metal oxide film of 100 or more, for example, 100 to 700, for example, 200 to 700, for example, 300 to 700. Thus, the composition for a semiconductor process can be variously used in a semiconductor process where such selective activity is required.

In addition, the composition for a semiconductor process may have an etching selectivity ratio for a metal nitride film to a metal film of 200 or more, for example, 200 to 700, for example, 300 to 700.

As will be described below, the “etching selectivity ratio” refers to the relative ratio of etching rates of a metal film, a metal oxide film, and a metal nitride film when an etching process is carried out for each of the metal film, the metal oxide film, and the metal nitride film using the composition for a semiconductor process at a temperature of about 150° C. to about 200° C.

In another embodiment, there is provided a semiconductor process, which is carried out using the composition for a semiconductor process.

Specifically, the semiconductor process comprises a cleaning process wherein an organic substance or an inorganic substance is selectively cleaned using the composition for a semiconductor process; a removal process wherein an organic substance or an inorganic substance is selectively removed using the composition for a semiconductor process; or both of them.

That is, the semiconductor process may comprise a cleaning process using the composition for a semiconductor process; a removal process using the composition for a semiconductor process; or both of them,

The composition for a semiconductor process may be used to selectively clean or remove a specific organic substance or a specific inorganic substance in the cleaning process or the removing process. Since the composition for a semiconductor process has a specific reactivity to a specific organic substance or a specific inorganic substance, it may be possible to selectively clean/remove the substance by using it.

Specifically, in the cleaning process or the removing process, other substances than a metal; an organic substance containing the metal; an oxide of the metal may be selectively cleaned or removed.

In such event, the metal may comprise at least one selected from the group consisting of germanium (Ge), silicon (Si), aluminum (Al), titanium (Ti), zirconium (Zr), hafnium (Hf), and tantalum (Ta).

Since the composition for a semiconductor process forms a protective film for a film substance made of the metal, a film substance made of the organic substance containing the metal, or a film substance made of the oxide of the metal, the other components nearby except the above can be removed or cleaned.

For example, the inorganic substance to be selectively removed using the composition for a semiconductor process may include a metal nitride film or a degenerated metal nitride film. In addition, the organic substance to be selectively removed using the composition for a semiconductor process may include an acrylic resin, a urethane resin, and the like.

In an embodiment, the semiconductor process may be a semiconductor fabricating process. The semiconductor fabricating process generally comprises an oxidation process, an exposure process, an etching process, an ion implantation process, a deposition process, a polishing process, a cleaning process, and an ashing process.

In such event, the step of selectively cleaning the organic substance or the inorganic substance using the composition for a semiconductor process may be carried out during at least one process selected from an ion implantation process, an etching process, and an ashing process.

That is, the process of cleaning an organic substance or an inorganic substance using the composition for a semiconductor process may be carried out before, after, and/or during each of an ion implantation process, an etching process, and an ashing process in the course of fabricating a semiconductor.

In the ion implantation process, dopant ions are implanted into a wafer to make it a semiconductor. In the etching process, the surface of a wafer on which the photoresist film pattern has been formed is selectively removed. In the ashing process, the degenerated resist material is carbonized and then removed when a photoresist is removed.

In the respective processes, when the unnecessary components are cleaned, while the parts made of the metal, the organic substance containing the metal, the oxide of the metal, or the like need not be damaged, the cleaning process may be carried out using the composition for a semiconductor process.

In addition, the step of selectively removing the organic substance or the inorganic substance using the composition for a semiconductor process may be carried out during at least one process selected from an exposure process, a deposition process, and an etching process.

That is, the process of removing an organic substance or an inorganic substance using the composition for a semiconductor process may be carried out before, after, and/or during each of an exposure process, a deposition process, and an etching process in the course of fabricating a semiconductor.

In the exposure process, a circuit pattern is formed on the surface of a wafer by using a mask having an image of a circuit. In the deposition process, a material having electrical characteristics is deposited on a wafer.

In the respective processes, when the unnecessary components are cleaned, while the parts made of the metal, the organic substance containing the metal, the oxide of the metal, or the like need not be damaged, the removing process may be carried out using the composition for a semiconductor process.

The step of selectively cleaning or removing the organic substance or the inorganic substance using the composition for a semiconductor process may be carried out at a temperature of about 20° C. to about 300° C., for example, about 20° C. to about 70° C., for example, about 150° C. to about 180° C. The process temperature may be appropriately set by the boiling points of the first component and the second component of the composition for a semiconductor process.

### Example

Hereinafter, specific embodiments of the present invention will be described. However, the embodiments described below are intended only to illustrate or explain the present invention. The present invention should not be limited thereto.

### Example and Comparative Example

Each experimental beaker equipped with a magnetic bar was charged with the first component, the second component, the solvent, and the additive in the kind and content (% by weight) as shown in Table 1 below, followed by stirring thereof at a speed of 500 rpm at room temperature for 4 hours to prepared a composition for a semiconductor process.

TABLE 1

| | First | | Second | | Additive | | | |
|---|---|---|---|---|---|---|---|---|
| | component | | component | | | Con- | Solvent | |
| | Kind | Content | Kind | Content | Kind | tent | Kind | Content |
| Ex. 1 | A-1 | 0.5 | B-1 | 0.01 | — | — | D-1 | Balance |
| Ex. 2 | A-1 | 0.5 | B-1 | 0.5 | — | — | D-1 | Balance |
| Ex. 3 | A-1 | 0.5 | B-7 | 0.02 | — | — | D-1 | Balance |
| Ex. 4 | A-1 | 0.5 | B-7 | 0.1 | — | — | D-1 | Balance |
| Ex. 5 | A-1 | 0.5 | B-1 | 0.1 | C-1 | 2.5 | D-1 | Balance |
| Ex. 6 | A-2 | 1 | B-2 | 0.05 | — | — | D-1 | Balance |
| Ex. 7 | A-2 | 1 | B-3 | 0.05 | — | — | D-1 | Balance |
| Ex. 8 | A-2 | 5 | B-5 | 0.05 | — | — | D-1 | Balance |
| Ex. 9 | A-2 | 5 | B-4 | 0.05 | — | — | D-1 | Balance |
| Ex. 10 | A-2 | 5 | B-6 | 0.05 | — | — | D-1 | Balance |
| Ex. 11 | A-2 | 5 | B-9 | 0.05 | — | — | D-1 | Balance |
| Ex. 12 | A-3 | 5 | B-10 | 0.05 | — | — | D-1 | Balance |
| Ex. 13 | A-3 | 5 | B-8 | 0.05 | — | — | D-1 | Balance |
| Ex. 14 | A-3 | 5 | B-8 | 0.05 | — | — | D-2 | Balance |
| Ex. 15 | A-3 | 5 | B-8 | 0.05 | — | — | D-3 | Balance |
| Ex. 16 | A-4 | 5 | B-3 | 0.01 | — | — | D-1 | Balance |
| Ex. 17 | A-4 | 10 | B-5 | 0.01 | — | — | D-1 | Balance |
| Ex. 18 | A-4 | 10 | B-4 | 0.01 | C-1 | 1 | D-1 | Balance |
| Ex. 19 | A-5 | 85 | B-1 | 0.01 | — | — | D-1 | Balance |
| Ex. 20 | A-5 | 85 | B-1 | 0.1 | — | — | D-1 | Balance |
| Ex. 21 | A-5 | 85 | B-2 | 0.1 | — | — | D-1 | Balance |
| Ex. 22 | A-5 | 85 | B-5 | 0.1 | — | — | D-1 | Balance |
| Ex. 23 | A-5 | 85 | B-5 | 1 | — | — | D-1 | Balance |
| Ex. 24 | A-5 | 85 | B-4 | 0.1 | — | — | D-1 | Balance |
| Ex. 25 | A-5 | 85 | B-6 | 0.1 | — | — | D-1 | Balance |
| Ex. 26 | A-5 | 85 | B-7 | 0.1 | — | — | D-1 | Balance |
| Ex. 27 | A-5 | 85 | B-8 | 0.1 | — | — | D-1 | Balance |
| Ex. 28 | A-5 | 85 | B-9 | 0.1 | — | — | D-1 | Balance |
| C. Ex. 1 | A-1 | 0.5 | — | — | — | — | D-1 | Balance |
| C. Ex. 2 | A-1 | 0.5 | B-1 | 0.001 | — | — | D-1 | Balance |
| C. Ex. 3 | A-1 | 0.5 | B-7 | 2 | — | — | D-1 | Balance |
| C. Ex. 4 | A-2 | 1 | — | — | — | — | D-1 | Balance |
| C. Ex. 5 | A-2 | 5 | — | — | — | — | D-1 | Balance |
| C. Ex. 6 | A-5 | 85 | — | — | — | — | D-1 | Balance |
| C. Ex. 7 | A-5 | 85 | B-1 | 0.001 | — | — | D-1 | Balance |
| C. Ex. 8 | A-5 | 85 | B-7 | 2 | — | — | D-1 | Balance |

First Component

A-1: hydrofluoric acid

A-2: sulfuric acid

A-3: acetic acid

A-4: oxalic acid

A-5: phosphoric acid

Second Component

B-1: germanium tetrachloride (compound of the above Formula 1-1)

B-2: germanium dichloride (compound of the above Formula 1-2)

B-3: germanium dioxide (compound of the above Formula 1-3)

B-4: tetrakis(trimethylsiloxy)germanium (compound of the above Formula 1-4)

B-5: trimethyl germyl trichlorosilane (compound of the above Formula 1-5)

B-6: 3-(trihydroxy germyl)propionic acid (compound of the above Formula 1-6)

B-7: tetraethoxygermanium (compound of the above Formula 1-7)

B-8: tetramethoxygermanium (compound of the above Formula 1-8)

B-9: tetraisopropoxygermanium (compound of the above Formula 1-9)

B-10: bis(2-carboxyethylgermanium sesquioxide) (compound of the above Formula 1-10)

Additive

C-1: ammonium fluoride

Solvent

D-1: water

D-2: dimethyl sulfoxide

D-3: NMP

Evaluation

### Test Example 1

### Evaluation of Cleanability

The compositions for a semiconductor process prepared in Examples 1 to 18 and Comparative Examples 1 to 5 were each evaluated for the cleanability thereof.

Specifically, a germanium (Ge) film having a thickness of 1000 Å and a hafnium oxide (HfO₂) film having a thickness of 500 Å were formed on a silicon wafer. Subsequently, a photoresist was uniformly coated thereon, which was then maintained at 150° C. for 10 minutes to form a thin film. Subsequently light having a wavelength of 365 nm was irradiated at a rate of 200 mJ/cm² onto the thin film using an ultra-high-pressure mercury lamp (USH-250D, Ushio Denki Co., Ltd.) under the atmospheric conditions. No separate optical filter was used.

The thin film irradiated with an ultraviolet ray was immersed in a developer of an aqueous solution of tetramethylammonium hydroxide (TMAH) for 80 seconds for the development thereof. Subsequently, it was rinsed with distilled water, dried with nitrogen gas, and heated in a heating oven at 150° C. for 10 minutes to form a pattern. Subsequently, it was sequentially subjected to an ion implantation process, an etching process, and an aching process to prepare a specimen.

The compositions for a semiconductor process of Examples 1 to 18 and Comparative Examples 1 to 5 were each maintained at a constant temperature of 60° C. Then, the prepared specimen was immersed therein for 2 minutes. The specimen was then taken out and rinsed with water for 1 minute. It was then completely dried with nitrogen gas, and the cleaning effect was checked by scanning electron microscope (SEM).

Here, the evaluation criteria are as follows. The results are as shown in Table 2 below.

<Evaluation Criteria>

Excellent: 99% or more removed

Good: 90% to less than 99% removed

Normal: 80% to less than 90% removed

Bad: less than 80% removed

### Test Example 2

### Evaluation of Corrosion

The compositions for a semiconductor process of Examples 1 to 18 and Comparative Examples 1 to 5 were each evaluated for the corrosion thereof.

The compositions for a semiconductor process of Examples 1 to 18 and Comparative Examples 1 to 5 were each maintained at a constant temperature of 60° C. Then, the specimen prepared according to Test Example 1 was immersed therein for 10 minutes. The specimen was then taken out and rinsed with water for 1 minute. It was then completely dried with nitrogen gas, and the corrosion effect was checked by scanning electron microscope (SEM). The etching rate was calculated by dividing the changes in the film thickness by time for each film substance. The results are shown in Table 2 below

TABLE 2

Corrosion (Å/min)

| | Cleanability | Ge | HfO₂ |
|---|---|---|---|
| Ex. 1 | Excellent | 2.0 | 1.7 |
| Ex. 2 | Excellent | — | — |
| Ex. 3 | Excellent | 1.5 | 0.9 |
| Ex. 4 | Excellent | — | — |
| Ex. 5 | Excellent | — | — |
| Ex. 6 | Excellent | 2.5 | — |
| Ex. 7 | Excellent | 1.8 | — |
| Ex. 8 | Excellent | 1.2 | — |
| Ex. 9 | Excellent | 1.5 | — |
| Ex. 10 | Excellent | 0.7 | — |
| Ex. 11 | Excellent | 1.8 | — |
| Ex. 12 | Good | 1.5 | 0.3 |
| Ex. 13 | Good | 1.3 | 0.4 |
| Ex. 14 | Good | — | — |
| Ex. 15 | Good | — | — |
| Ex. 16 | Good | 0.8 | 0.4 |
| Ex. 17 | Good | 0.6 | 0.5 |
| Ex. 18 | Excellent | 1.1 | 0.9 |
| C. Ex. 1 | Excellent | Greater than 100 | Greater than 100 |
| C. Ex. 2 | Excellent | Greater than 100 | Greater than 100 |
| C. Ex. 3 | Bad | — | — |
| C. Ex. 4 | Excellent | 34 | 1.2 |
| C. Ex. 5 | Excellent | 67 | 1.6 |

### Test Example 3

### Evaluation of Etchability

The compositions for a semiconductor process of Examples 19 to 28 and Comparative Examples 6 to 8 were each evaluated for the etchability thereof for a nitride film.

Prepared were a sample in which a silicon nitride (Si₃N₄) film having a thickness of 2,000 Å was formed on a silicon wafer by a chemical vapor deposition (CVD) method; a sample in which a silicon oxide (SiOₓ) film having a thickness of 200 Å was formed on a silicon wafer using a chemical vapor deposition (CVD) method; and a silicon single crystal sample having a thickness of 1500 Å.

Subsequently, each sample was immersed in each composition for a semiconductor process of Examples 19 to 28 and Comparative Examples 6 to 8, which was being maintained at 160° C. in a stirring tank made of quartz and stirred at a speed of 500 rpm, to carry out an etching process. Upon completion of the etching, process, the sample was rinsed with ultrapure water and then dried using a drying apparatus.

Then, the thickness of each sample upon the etching was measured using a scanning electron microscope (SEM) and an ellipsometer. The etching rate was measured for the changes in the thin film thickness before and after the etching process. The results are as shown in Table 3 below.

The etching selectivity ratio was calculated by obtaining the etching rate ratio for each of the silicon nitride film, the silicon oxide film, and the silicon single crystal sample. The results are as shown in Table 3 below.

TABLE 3

| | |
|---|---|
| Corrosion (Å/min) | Etching selectivity ratio |

| | SiOx | Si₃N₄ | Si | Si₃N₄/Si | Si₃N₄/SiOx |
|---|---|---|---|---|---|
| Ex. 19 | 0.4 | 68 | 0.1 | 680 | 170 |
| Ex. 20 | 0.2 | 67 | 0.3 | 223 | 335 |
| Ex. 21 | 0.2 | 66 | 0.2 | 330 | 330 |
| Ex. 22 | 0.2 | 67 | 0.1 | 670 | 335 |
| Ex. 23 | 0.1 | 60 | 0.1 | 600 | 600 |
| Ex. 24 | 0.2 | 64 | 0.2 | 320 | 320 |
| Ex. 25 | 0.2 | 66 | 0.3 | 220 | 330 |
| Ex. 26 | 0.2 | 68 | 0.2 | 340 | 340 |
| Ex. 27 | 0.3 | 66 | 0.3 | 220 | 220 |
| Ex. 28 | 0.2 | 64 | 0.3 | 213 | 320 |
| C. Ex. 6 | 4.3 | 66 | 2.7 | 24 | 15 |
| C. Ex. 7 | 4.0 | 63 | 2.4 | 26 | 16 |
| C. Ex. 8 | 0.4 | 27 | 0.1 | 270 | 68 |

As described above, the compositions for a semiconductor process of Examples 1 to 28 produce an advantageous effect in terms of protection for a metal or a metal oxide film, as compared with the compositions for a semiconductor process of Comparative Examples 1 to 8. In addition, they produce an excellent effect in the removal and etching of a metal nitride film.

1. A composition for a semiconductor process, which comprises a first component comprising an inorganic acid or an organic acid; and
a second component comprising a compound represented the following Formula 1 or a compound represented by the following Formula 2: 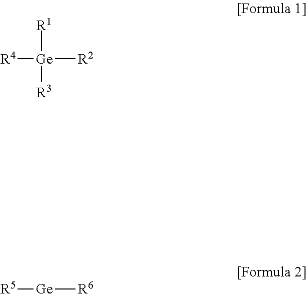
in the above Formulae 1 and 2,
R¹ to R⁶ are each independently selected from hydrogen, a substituted or unsubstituted C₁-C₃₀ alkyl group, a substituted or unsubstituted C₁-C₃₀ alkoxy group, a substituted or unsubstituted C₂-C₃₀ alkenyl group, a substituted or unsubstituted C₂-C₃₀ alkynyl group, a substituted or unsubstituted C₆-C₃₀ aliphatic ring group, a substituted or unsubstituted C₄-C₃₀ heteroaliphatic ring group, a substituted or unsubstituted C₆-C₃₀ aromatic ring group, a substituted or unsubstituted C₄-C₃₀ heteroaromatic ring group, a substituted or unsubstituted amine group, a hydroxyl group, a carbonyl group, a carboxyl group, a halogen group, an oxide (═O) group, and a group of the following Formula 3, 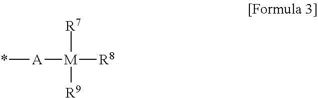
in the above Formula 3,
M is silicon (Si) or germanium (Ge),
A is selected from a single bond, a substituted or unsubstituted C₁-C₃₀ alkylene group, a substituted or unsubstituted C₂-C₃₀ alkenylene group, a substituted or unsubstituted C₂-C₃₀ alkynylene group, a substituted or unsubstituted divalent C₆-C₃₀ aliphatic ring group, a substituted or unsubstituted divalent C₄-C₃₀ heteroaliphatic ring group, a substituted or unsubstituted divalent C₆-C₃₀ aromatic ring group, a substituted or unsubstituted divalent C₄-C₃₀ heteroaromatic ring group, a substituted or unsubstituted divalent amine group, —O—, —S—, —S(═O)₂— and —C(═O)—, and
R⁷ to R⁹ are each independently selected from hydrogen, a substituted or unsubstituted C₁-C₃₀ alkyl group, a substituted or unsubstituted C₁-C₃₀ alkoxy group, a substituted or unsubstituted C₂-C₃₀ alkenyl group, a substituted or unsubstituted C₂-C₃₀ alkynyl group, a substituted or unsubstituted C₆-C₃₀ aliphatic ring group, a substituted or unsubstituted heteroaliphatic ring group, a substituted or unsubstituted C₆-C₃₀ aromatic ring group, a substituted or unsubstituted C₄-C₃₀ heteroaromatic ring group, a substituted or unsubstituted amine group, a hydroxyl group, a carbonyl group, a carboxyl group, a halogen group, and an oxide (═O) group.

2. The composition for a semiconductor process of claim 1, which further comprises a reaction product of the first component and the second component.

3. The composition for a semiconductor process of claim 1, which further comprises a solvent, wherein the solvent comprises water or a polar organic solvent.

4. The composition for a semiconductor process of claim 3, wherein the polar organic solvent comprises at least one selected from the group consisting of alcohol, glycol, lactone, lactam, sulfoxide, sulfone, amide, urea, imidazolidinone, nitrile, and pyrrolidone.

5. The composition for a semiconductor process of claim 1, wherein the inorganic acid comprises at least one selected from the group consisting of sulfuric acid, nitric acid, phosphoric acid, silicic acid, boric acid, hydrochloric acid, hydrofluoric acid, and perchloric acid.

6. The composition for a semiconductor process of claim 1, wherein the organic acid comprises at least one selected from the group consisting of acetic acid, formic acid, gluconic acid, lactic acid, oxalic acid, and hydrocarbonic acid.

7. The composition for a semiconductor process of claim 1, which comprises the second component in an amount of greater than 0.001% by weight less than 2% by weight.

8. The composition for a semiconductor process of claim 1, which comprises the first component in an amount of 50% by weight to 99% by weight.

9. The composition for a. semiconductor process of claim 1, which comprises the first component in an amount of 0.5% by weight to 30% by weight.

10. The composition for a semiconductor process of claim 1, which has an etching selectivity ratio for a metal nitride film to a metal film of 200 or more, and
an etching selectivity ratio for a metal nitride film to a metal oxide film of 100 or more.

11. A semiconductor process, which comprises a cleaning process wherein an organic substance or an inorganic substance is selectively cleaned using the composition for a semiconductor process of claim 1; a removal process wherein an organic substance or an inorganic substance is selectively removed using the composition for a semiconductor process; or both of them,

12. The semiconductor process of claim 11, wherein the cleaning process or the removing process is carried out at a temperature of 20° C. to 300° C.

13. The semiconductor process of claim 11, wherein the cleaning process or the removing process is a process in which other substances than a metal; an organic substance containing the metal; an oxide of the metal are selectively cleaned or removed, and
the metal comprises at least one selected from the group consisting of germanium. (Ge), silicon (Si), aluminum (Al), titanium (Ti), zirconium (Zr), hafnium (Hf), and tantalum (Ta).
